(19) United States
(12) Patent Application Publication
(10) Pub. No.: US 2011/0319006 A1
(43) Pub. Date: Dec. 29, 2011

(54) VENT HOOD APPARATUS FOR DATA CENTER

(75) Inventor: Adam Gilder, Fort Worth, TX (US)

(73) Assignee: VERIZON PATENT AND LICENSING INC., Basking Ridge, NJ (US)

(21) Appl. No.: 12/825,500

(22) Filed: Jun. 29, 2010

(51) Int. Cl. H05K 5/02; F24F 7/00

(52) U.S. Cl. 454/184; 454/293; 454/237

(57) ABSTRACT

An apparatus is provided including a vent hood having an intake opening on a lower side thereof and a return opening on an upper side thereof. The apparatus also includes a return duct connected to the return opening and configured to connect to an air conditioner of a data center. The vent hood and the return duct are configured to extend downward from a ceiling of the data center to a location above an electronic component cabinet.

### BACKGROUND INFORMATION

Modern data centers can house large numbers of electronic components that can generate large amounts of heat when in operation. Related to this heat problem is that of power and cooling. While sufficient power needs to be provided to the numerous electronic components, the need to cool them is imperative. These competing engineering issues can effectively constrain the capacity of the data centers. Therefore, there is a need for an approach that provides for efficient cooling of components to enable greater capacity of data center facilities.

### BRIEF DESCRIPTION OF THE DRAWINGS

Various exemplary embodiments are illustrated by way of example, and not by way of limitation, in the figures of the accompanying drawings in which like reference numerals refer to similar elements and in which:

FIG. 1 is a perspective view of a vent hood apparatus for an air conditioning system for a data center, according to an exemplary embodiment;

FIG. 2 is a perspective view of a vent hood apparatus for an air conditioning system for a data center, according to another exemplary embodiment;

FIG. 3A is an exploded, bottom view of a vent hood apparatus where a light fixture assembly is shown in an exploded view outside of a vent hood, according to a further exemplary embodiment;

FIG. 3B is a side view of the vent hood apparatus of FIG. 3A shown in an assembled view;

FIG. 4 is a perspective view of a vent hood apparatus for an air conditioning system for a data center connected to a computer room air conditioner, according to yet another exemplary embodiment;

FIG. 5 is a perspective view of an air conditioning system utilizing an exemplary cabinet configuration of the background art; and

FIG. 6 is a computational fluid dynamics image showing a temperature distribution of airflow around an exemplary cabinet configuration, such as that shown in FIG. 5, utilizing a background art air conditioning system.

### DESCRIPTION OF THE PREFERRED EMBODIMENT

A preferred apparatus, method, and system for providing efficient cooling of components in a data center facility are described. In the following description, for the purposes of explanation, numerous specific details are set forth in order to provide a thorough understanding of the preferred embodiments of the invention. It is apparent, however, that the preferred embodiments may be practiced without these specific details or with an equivalent arrangement. In other instances, well-known structures and devices are shown in block diagram form in order to avoid unnecessarily obscuring the preferred embodiments of the invention.

Although various exemplary embodiments are described with respect to a data center facility, it is contemplated that these embodiments have applicability to any facility used to house electronic component hardware.

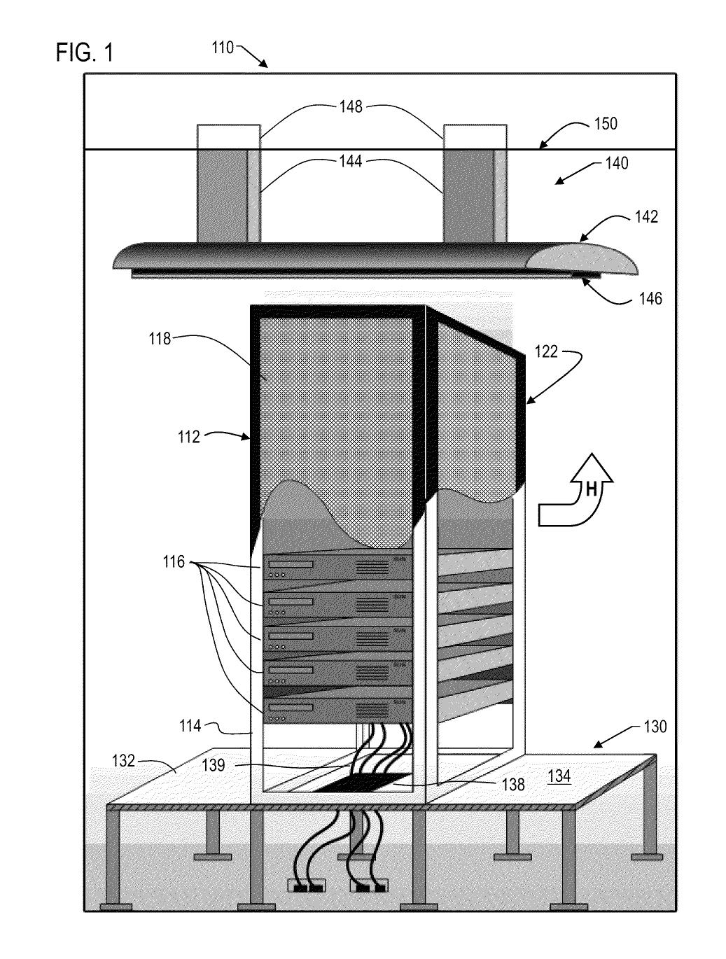

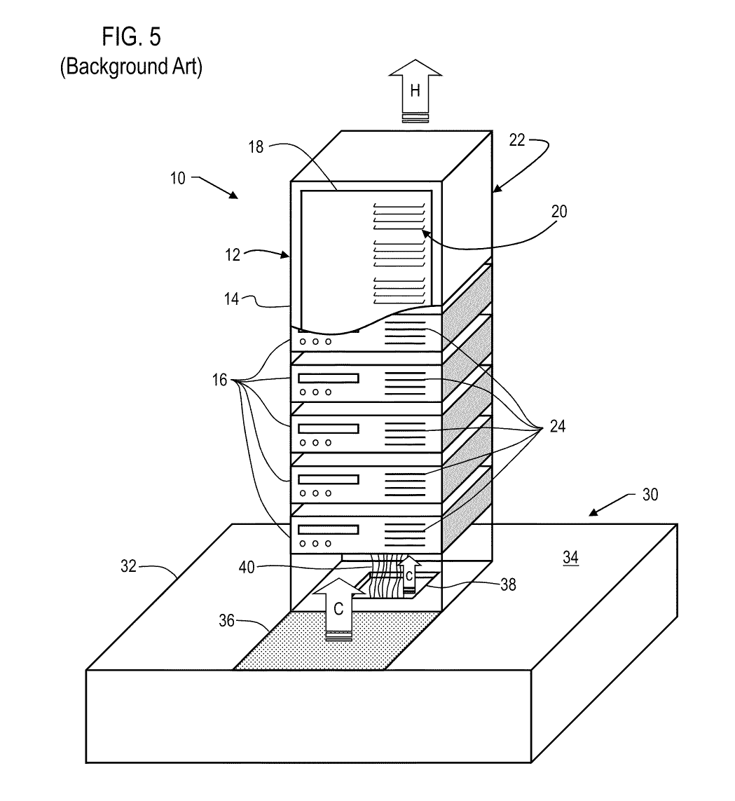

FIG. 1 is a perspective view of a vent hood apparatus for an air conditioning system for a data center, according to an exemplary embodiment. To better appreciate the advantages of embodiments of the invention, it is instructive to examine an exemplary cabinet configuration of the background art, shown in FIG. 5.

FIG. 5 is a perspective view of an air conditioning system utilizing an exemplary cabinet configuration of the background art. Stacks of computer components are typically housed within electronic component cabinets, an example of which is depicted in FIG. 5. FIG. 5 depicts a data center facility 10 that includes an exemplary electronic component cabinet 12 having a frame 14 with a plurality of electronic components 16, such as computer processors, mounted therein. The cabinet 12 has a front panel or door 18 that allows access to the electronic components 16.

In order to allow for the cooling of the electronic components within the cabinet 12, the front panel 18 has air intakes 20 and the rear 22 of the cabinet has air outlets (not shown). The air intakes 20 correspond to cooling intakes 24 on the front of the electronic components 16, and the outlets on the rear 22 of the cabinet 12 correspond to outlets (not shown) on the rear of the electronic components 16. The electronic components 16 typically include a cooling fan (not shown) within the housing thereof that forces cooling air into the component housing through the cooling intakes 24 on the front of the electronic components 16 and out through the outlets on the rear of the electronic components 16, in order to remove heat from the housing of the components.

Therefore, in order to cool one or more cabinets 12 provided within a room of a data center facility, a raised-floor plenum type air conditioning system 30 can be provided. The system 30 is fed by a heating, ventilating, and air-conditioning (HVAC) system that, during cooling, pumps cooling air into an interior of an under-floor plenum 32. The frame 14 of the cabinet 12 is mounted to an upper surface 34 of the plenum 32, and the plenum has an air conditioning outlet (e.g., a perforated floor tile) 36 that is provided adjacent the front side of the cabinet 12. Additionally, the plenum 32 has a hole (or cable egress) 38 through which all of the electrical wiring 40 for the electronic components 16 in the cabinet 12 extend.

The raised-floor plenum type air conditioning system 30 is intended to cool the components 16 within the cabinet 12 by forcing cooling air, C, up through the air conditioning outlet 36, which will then be sucked in through the air intakes 20 and in through the cooling intakes 24 by the cooling fans in the components 16, and then the heated exhaust air will be discharged out the rear 22 of the cabinet and the heated air, H, will rise and be discharged from the room and/or circulated back through the air conditioning system. In a conventional data center, HVAC system includes an intake opening (not shown) that is flush with the ceiling tiles of the data center, which attempt to collect the heated air, H. However, such intake openings fail to provide efficient collection of the heated air, H, and allow for recirculation of the heated air, H, within the room of the data center, which has been determined to significantly reduce the overall efficiency of the air conditioning system.

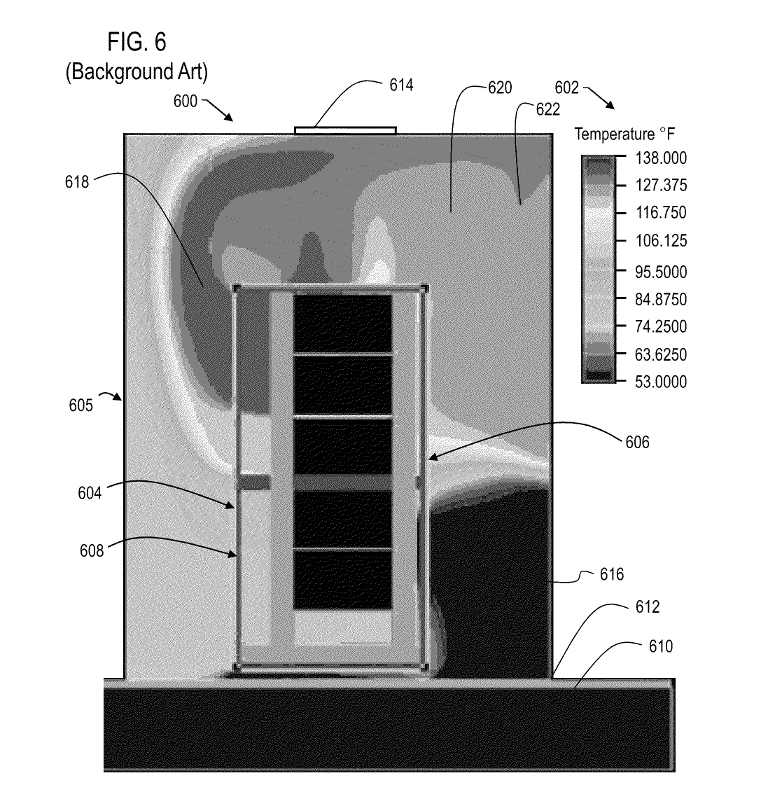

FIG. 6 is a computational fluid dynamics image 600 showing a temperature distribution of airflow around an exemplary cabinet configuration, such as that shown in FIG. 5, utilizing a background art air conditioning system. The image 600 includes a temperature scale 602 that indicates the temperature of the airflow. The image 600 shows a cabinet 604 housed within a data center room 605. The cabinet 604 has a front side 606 with air inlets that allow air to flow into the cabinet 604, and a rear side 608 with air outlets that allow air to flow out of the cabinet 604.

The image 600 shows a raised-floor plenum 610 of an air conditioning system. The cabinet 604 is mounted on an upper surface of the plenum 610, and an air conditioning outlet 612 is provided adjacent to the front side 606 of the cabinet 604. Additionally, a ceiling intake 614 is provided in the ceiling of the data center room 605. Thus, the air conditioning outlet 612 releases cool air, as can be seen by the dark area 616, which indicates a low temperature airflow on the temperature scale 602. The cool air from the air conditioning outlet 612 then enters the front side 606 of the cabinet 604, where it is heated by the electronic components within the cabinet, and then released from the rear side 608 of the cabinet as hot air, as can be seen by the dark area 618, which indicates a high temperature airflow on the temperature scale 602.

As can be seen in the image 600, the ceiling intake 614 does not efficiently collect the heated air exiting from the rear of the cabinet 604 even when a high rate of suction is used in an attempt to draw the hot air into the ceiling intake 614. Due in part by the suction from fans of the electronic components drawing air in the front side 606 of the cabinet 604, the hot air exiting from the rear side 608 of the cabinet 604 circulates over the top of the cabinet 604 and loops around towards the front side 606, as can be seen by the relatively hot air in front area 620 and circulation area 622 of hot airflow. Thus, this circulation allows for the upper front half of the cabinet 604 to receive an airflow in the range of, for example, about 90° F. to about 98° F. Such a high temperature of circulating airflow can significantly raise the temperature of the electronic components within the cabinet 604, which can significantly reduce the life of the electronic components. Typical data center components can have a recommended maximum intake temperature of, for example, about 75° F., and thus the above temperature range can lead to a significant deterioration in the operational lifespan of the electronic components, for example, by increasing the likelihood of disk failures, etc. Additionally, this recirculation reduces the efficiency of the HVAC system, and it requires that the HVAC system utilize fans at high operational levels and high capacity in order to achieve even a basic level of cooling in the data center.

Data suggests that data centers account for about 4% of energy consumed in the United States. Also, data suggests that, of the energy used by data centers, about 30% is used by the electronic components themselves, and about 60% is used by HVAC systems used to cool the data center. Raised floor data centers face an increasing concern of lacking proper HVAC capacity to accommodate rapid heat loads generated by newer generation equipment. Loads have doubled from 2000 to 2008 and are expected to continue in this direction. Thus, improvements in efficiency of HVAC systems of data centers are needed not only to provide a significant decrease in the energy consumption of such data centers, but also to ensure that the electronic components can be housed in a cool facility that can extend the lifespan of such electronic components.

Various methods of heat removal have been considered which include in-cabinet heat extraction and water cooling of computing components. However, methods such as this have proven to be costly with required equipment refreshes or downtime of equipment. Embodiments of the vent hood apparatus of the invention advantageously provide a solution to better direct hot air away from the electronic equipment and decrease amount of recirculation of hot air within the data center back towards the intake of the electronic components. Embodiments of the vent hood apparatus of the invention advantageously provide a solution to extract hot air back to the intake of computer room air conditioners while reducing energy consumption, increasing the lifespan of equipment due to a cooler environment while abiding by local fire codes as obstruction of overhead sprinklers is avoided.

Embodiments of the vent hood apparatus of the invention can be used in conjunction with standard raised floor data center environments that have hot/cold isle energy efficient configurations. The vent hood apparatus can be configured to extract heat created by high voltage computing equipment to prevent hot/cold air mixing and increase effectiveness of computer room air conditioner (CRAC) units while reducing energy consumption.

FIG. 1 is a perspective view of a vent hood apparatus for an air conditioning system for a data center, according to an exemplary embodiment. FIG. 1 depicts a data center facility 110 that includes an exemplary electronic component cabinet 112 having a frame 114 with a plurality of electronic components 116, such as computer processors, mounted therein. The cabinet 112 has a front side 118 with a panel or door that allows access to the electronic components 116.

In order to allow for the cooling of the electronic components within the cabinet 112, the front side 118 has air intakes and a rear side 22 of the cabinet 112 has air outlets (not shown). The air intakes correspond to cooling intakes on the front of the electronic components 116, and the outlets on the rear 122 of the cabinet 112 correspond to outlets (not shown) on the rear of the electronic components 116. The electronic components 116 typically include a cooling fan (not shown) within the housing thereof that forces cooling air into the component housing through the cooling intakes on the front of the electronic components 116 and out through the outlets on the rear of the electronic components 116, in order to remove heat from the housing of the components.

In order to cool one or more cabinets 112 provided within a room of a data center facility 110, a raised-floor plenum type air conditioning system 130 can be provided. The system 130 is fed by a heating, ventilating, and air-conditioning (HVAC) system that, during cooling, pumps cooling air into an interior of an under-floor plenum 132. The frame 114 of the cabinet 112 is mounted to an upper surface 134 of the plenum 132, and the plenum has an air conditioning outlet (e.g., a perforated floor tile)(not shown) that is provided adjacent the front side 118 of the cabinet 112. Additionally, the plenum 132 has a hole (or cable egress) 138 through which all of the electrical wiring 139 for the electronic components 116 in the cabinet 112 extend.

The data center facility is provided with a vent hood apparatus 140 that includes a vent hood 142, and one or more return ducts 144. The vent hood apparatus 140 can also be provided with a light fixture assembly 146 mounted to the vent hood 142. The vent hood 142 can be provided having an inverted U-shaped configuration with an intake opening on a lower side thereof and one or more return openings on an upper side thereof, where the return openings are connected to a respective return duct to allow air to allow air to flow into the return openings and along through the return ducts 144. The return ducts 144 are connected to ducts 148, which are provided above ceiling panels of a drop ceiling 150 of the data center. The ducts 148 are connected to an air conditioner of the data center.

The vent hood and the return ducts are configured to extend downward from the ceiling 150 of the data center to a location above an electronic component cabinet 112. For example, the vent hood and the return duct are configured to extend downward from the ceiling such that the intake opening of the vent hood 142 is within about 6 inches to about 18 inches above an upper surface of the electronic component cabinet 112. The optimal distance between the opening of the vent hood 142 and the upper surface of the cabinet 112 can depend on, for example, the amount of suction being generated by the air conditioning unit. In one embodiment, the intake opening of the vent hood is located directly above the rear side surface of the cabinet 112, such that the hot air exiting the rear side 122 of the cabinet 112 can buoyantly travel upward and into the vent hood 142. The vent hood 142 is not attached to the electronic component cabinet 112, so that the cabinet 112 can be moved and relocated within the data center if desired and the vent hood apparatus 140 can be reconfigured based on a new arrangement of cabinets within the data center.

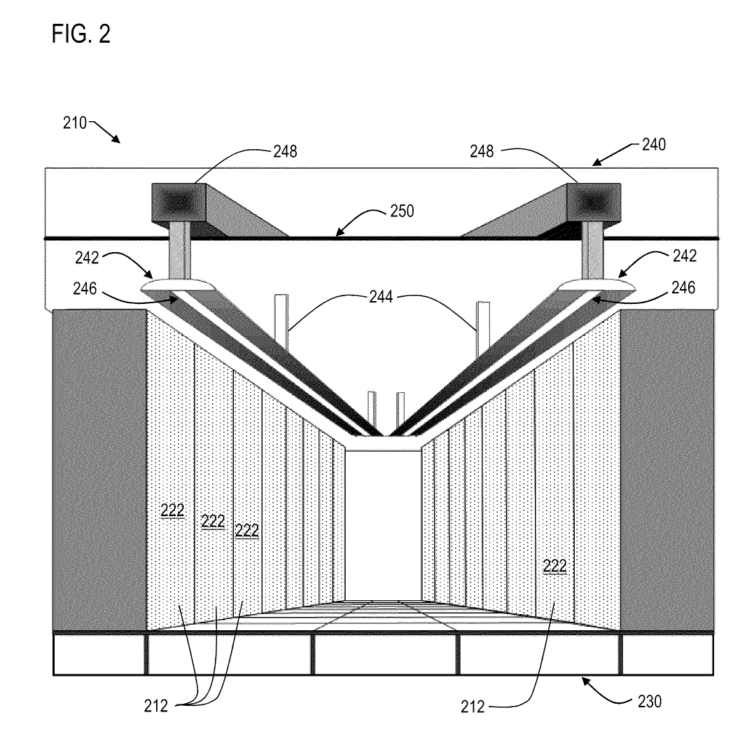

FIG. 2 is a perspective view of a vent hood apparatus for an air conditioning system for a data center, according to another exemplary embodiment. FIG. 2 depicts a data center facility 210 that includes rows of exemplary electronic component cabinets 212 that have rear sides 222 having air outlets that allow hot air to exhaust from the cabinets 212. In order to cool the cabinets 212 provided within a room of a data center facility 210, a raised-floor plenum type air conditioning system 230 is provided.

The data center facility 210 is provided with a vent hood apparatus 240 that includes vent hoods 142, each having plural return ducts 244. The vent hood apparatus 240 is provided with light fixture assemblies 246 mounted to each of the vent hoods 242. The return ducts 244 are connected to ducts 248, which are provided above ceiling panels of a ceiling 250 of the data center. The ducts 248 are connected to an air conditioner of the data center. The vent hood and the return ducts are configured to extend downward from the ceiling 250 of the data center to a location above the electronic component cabinets 212. In this embodiment, the intake openings of the vent hoods 242 are located directly above the rear side surface of the cabinets 212 along each row of cabinets, such that the hot air exiting the rear sides 222 of the cabinets 212 can buoyantly travel upward and into the vent hoods 242. The vent hoods 242 are not attached to the electronic component cabinets 212, so that the cabinets 212 can be rearranged within the data center if desired and the vent hood apparatus 240 can be reconfigured based on a new arrangement of cabinets within the data center.

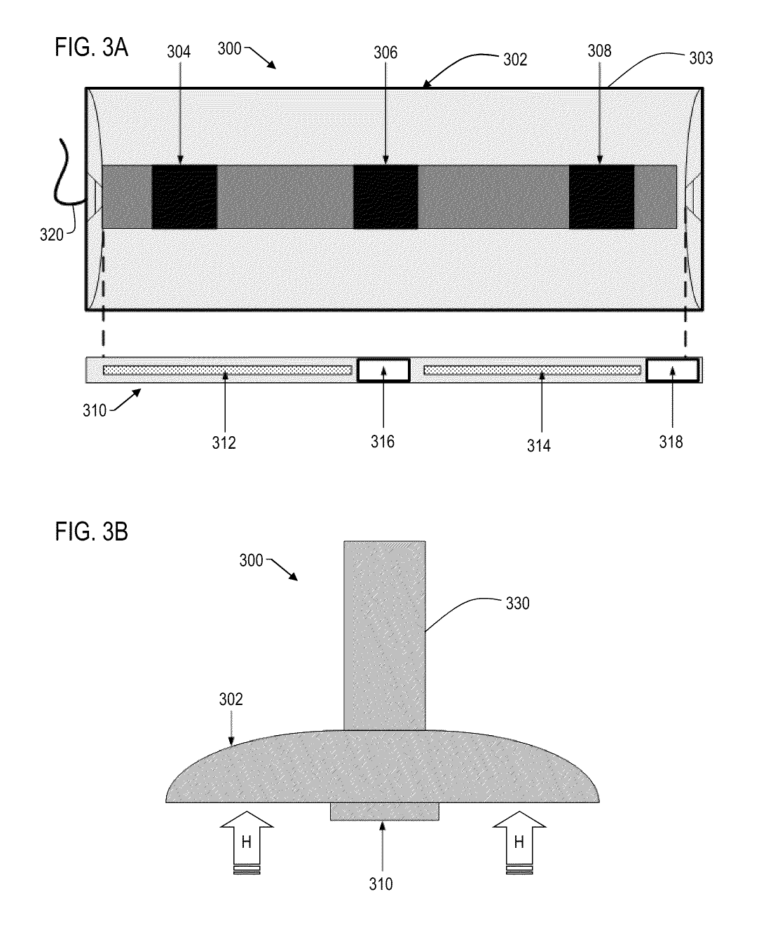

FIG. 3A is an exploded, bottom view of a vent hood apparatus where a light fixture assembly is shown in an exploded view outside of a vent hood, according to a further exemplary embodiment, and FIG. 3B is a side view of the vent hood apparatus of FIG. 3A shown in an assembled view.

The vent hood apparatus 300 includes a vent hood 302. The vent hood 302 has an inverted U-shaped configuration with an intake opening 303 on a lower side thereof and one or more return openings 304, 306, 308 on an upper side thereof, where the return openings 304, 306, 308 are connected to a respective return duct 330 to allow air to allow air to flow into the return openings and along through the return duct 330.

The vent hood apparatus 300 is also provided with a light fixture assembly 310 mounted to the vent hood 302. The light fixture assembly 310 includes one or more light sources mounted within the hood vent 302. The light source and light fixture assembly is mounted beneath the return openings 304, 306, 308 such that any heat generated by the light fixture assembly will buoyantly travel upwards into the return openings and flow to the air conditioning unit. In one embodiment, the light source is one or more incandescent light bulbs 312, 314, with respective light ballasts 316, 318. Gas discharge lamps, including fluorescent lamps, use a ballast to operate. The ballast provides a high initial voltage to initiate the discharge, then rapidly limits the lamp current to safely sustain the discharge. The light fixture assembly 310 is powered via a wire 320.

Accordingly, the vent hood apparatus 300 can use suction from fans of an air conditioning unit to collect hot air, H, from the electronic component cabinets through intake opening 303, around the light fixture assembly 310, and into the return openings 304, 306, 308, in order to circulate the hot air back to the air conditioning unit for cooling. The vent hood apparatus 300 advantageously extends downward from the ceiling of data center to a location above the cabinets, thereby allowing for efficient collection of hot air and a reduction in the recirculation of hot air within the data center room. The vent hood apparatus 300 advantageously provides more efficient collection of hot air, which not only provides better cooling of the electronic components within the cabinets by preventing recirculation, but also reduces the capacity of fans of the air conditioning unit needed to provide sufficient cooling of electronic component thus reducing the cost of operating the air conditioning unit and the size requirements of the air conditioning unit. Additionally, by more efficiently collecting the hot air, the vent hood apparatus 300 also increases the operational efficiency of the air conditioning unit, which typically operate at greater efficiency using hotter intake air than such a unit would operate at using lower temperature intake air. Also, the vent hood apparatus 300 can use the suction to collect hot air generated by heat from the light fixture assembly 310 into the return openings 304, 306, 308, in order to circulate the hot air back to the air conditioning unit for cooling, which can provide a significant reduction in the temperature of the data center. For example, a typical 20,000 square foot data center can produce 84,000 BTUs in heat by lighting alone, which can now be efficiently collected and sent to the air conditioning unit for cooling.

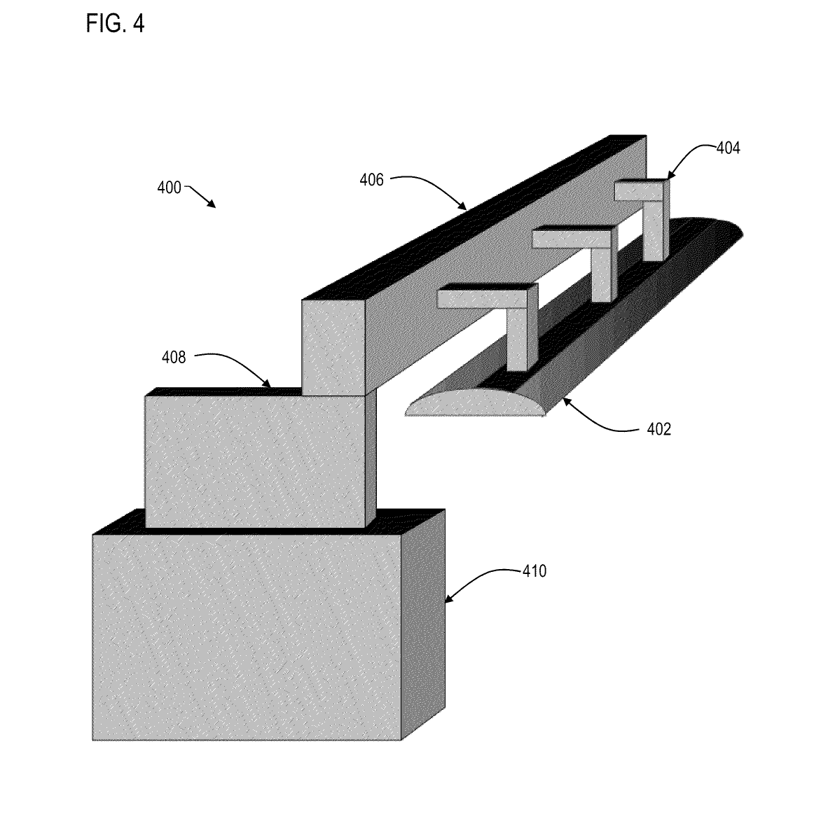

FIG. 4 is a perspective view of a vent hood apparatus 400 for an air conditioning system for a data center connected to a computer room air conditioner, according to yet another exemplary embodiment. The vent hood apparatus 400 includes a vent hood 402 connected to plural return ducts 404. Thus, the vent hood(s) can be located in hot isles behind all of the computing cabinets located in the data center. The return ducts 404 feed into a duct 406, which feeds into a return plenum 408 that can be connected to one or more ducts (i.e., duct 406, etc.). The return plenum 408 is connected to an HVAC system, such as a computer room air conditioner 410, which receives and cools the hot air before circulating the cooled air back into the data center room via a raised-floor or under-floor plenum (e.g., plenum 132 of FIG. 1, etc.).

While certain exemplary embodiments and implementations have been described herein, other embodiments and modifications will be apparent from this description. Accordingly, the invention is not limited to such embodiments, but rather to the broader scope of the presented claims and various obvious modifications and equivalent arrangements.

What is claimed is:

1. An apparatus comprising:
a vent hood having an intake opening on a lower side thereof and a return opening on an upper side thereof; and
a return duct connected to said return opening and configured to connect to an air conditioner of a data center,
wherein said vent hood and said return duct are configured to extend downward from a ceiling of the data center to a location above an electronic component cabinet.

2. The apparatus of claim 1, further comprising a light fixture assembly including a light source mounted within said hood vent.

3. The apparatus of claim 2, wherein said light source is mounted beneath said return opening.

4. The apparatus of claim 3, wherein said light source is an incandescent light bulb, and wherein said light fixture assembly includes a light ballast.

5. The apparatus of claim 1, wherein said vent hood has an inverted U-shaped configuration.

6. The apparatus of claim 1, wherein said vent hood and said return duct are configured to extend downward from the ceiling such that said intake opening is within about 6 inches to about 18 inches above an upper surface of the electronic component cabinet.

7. The apparatus of claim 1, wherein said vent hood includes a plurality of return openings, and wherein said apparatus further comprises a plurality of return ducts each connected to a respective return opening of said plurality of return openings.

8. The apparatus of claim 1, wherein said vent hood is not attached to the electronic component cabinet.

9. A system comprising:
an air conditioning plenum having an upper surface with an air conditioning outlet;
an electronic component cabinet attached to said upper surface of said air conditioning plenum, said electronic component cabinet having one or more air intakes on a first side thereof and one or more air outlets on a second side thereof, wherein said air conditioning outlet is provided at a location adjacent said first side of said electronic component cabinet; and
an apparatus including:
a vent hood having an intake opening on a lower side thereof and a return opening on an upper side thereof; and
a return duct connected to said return opening and configured to connect to an air conditioner of a data center,
wherein said vent hood and said return duct are configured to extend downward from a ceiling of the data center to a location above said electronic component cabinet.

10. The system of claim 9, further comprising a light fixture assembly including a light source mounted within said hood vent.

11. The system of claim 10, wherein said light source is mounted beneath said return opening.

12. The system of claim 11, wherein said light source is an incandescent light bulb, and wherein said light fixture assembly includes a light ballast.

13. The system of claim 9, wherein said vent hood has an inverted U-shaped configuration.

14. The system of claim 9, wherein said vent hood and said return duct are configured to extend downward from the ceiling such that said intake opening is within about 6 inches to about 18 inches above an upper surface of said electronic component cabinet.

15. The system of claim 9, wherein said vent hood includes a plurality of return openings, and wherein said apparatus further comprises a plurality of return ducts each connected to a respective return opening of said plurality of return openings.

16. The system of claim 9, wherein said vent hood is not attached to said electronic component cabinet.

17. A method comprising:
providing a vent hood having an intake opening on a lower side thereof and a return opening on an upper side thereof; and
providing a return duct connected to the return opening and configured to connect to an air conditioner of a data center,
wherein the vent hood and the return duct extend downward from a ceiling of the data center to a location above the electronic component cabinet.

18. The method of claim 17, further comprising providing a light fixture assembly including a light source mounted within the hood vent, wherein the light source is mounted beneath the return opening.

19. The method of claim 17, wherein the vent hood and the return duct extend downward from the ceiling such that the intake opening is within about 6 inches to about 18 inches above an upper surface of the electronic component cabinet.

20. The method of claim 17, wherein the vent hood is not attached to the electronic component cabinet.
